(19) United States
(12) Patent Application Publication
(10) Pub. No.: US 2024/0302206 A1
(43) Pub. Date: Sep. 12, 2024

(54) LIGHT DETECTION DEVICE AND ELECTRONIC DEVICE

(71) Applicant: SONY SEMICONDUCTOR SOLUTIONS CORPORATION, KANAGAWA (JP)

(72) Inventor: DAIZO TAKATA, KUMAMOTO (JP)

(21) Appl. No.: 18/549,389

(22) PCT Filed: Jan. 11, 2022
(86) PCT No.: PCT/JP2022/000450

§ 371 Date: Sep. 7, 2023

(30) Foreign Application Priority Data
Mar. 22, 2021 (JP) 2021-047244

(51) Int. Cl. G01J 1/04; G01J 1/44; H04N 25/11; H04N 25/76

(52) U.S. Cl. CPC G01J 1/0414; G01J 1/0492; G01J 1/44; H04N 25/11; H04N 25/76; G01J 2001/448

(57) ABSTRACT

Provided is a light detection device capable of suppressing optical color mixing while improving quantum efficiency QE. A substrate including a plurality of photoelectric conversion units and a wiring layer arranged on a side opposite to a light receiving surface of the substrate are provided. Then, the wiring layer includes a reflection layer formed so as to overlap at least a part of the plurality of photoelectric conversion units in a stacking direction in which the substrate and the wiring layer are stacked. Furthermore, the reflection layer includes a plurality of recesses each including a corner cube-shaped portion in each of portions overlapping the photoelectric conversion units on a surface on a side of the photoelectric conversion units.

### TECHNICAL FIELD

The present disclosure relates to a light detection device and an electronic device.

### BACKGROUND ART

In recent years, devices (light detection devices) that detect long-wavelength light are increasing. Long-wavelength light is poorly absorbed by silicon. Therefore, for example, when long-wavelength light is incident on a photoelectric conversion unit of the light detection device, incident light passes through the photoelectric conversion unit to exit to an adjacent photoelectric conversion unit, so that there is a possibility that quantum efficiency QE decreases. Furthermore, there is a possibility that optical color mixing (crosstalk) occurs because the incident light that exits is detected by the adjacent photoelectric conversion unit.

Here, as a technology of improving the quantum efficiency QE and suppressing the optical color mixing (crosstalk), for example, a technology of providing a pixel separation unit between the photoelectric conversion units has been proposed (refer to, for example, Patent Document 1). In the technology disclosed in Patent Document 1, incident light that passes through the photoelectric conversion unit and hit the pixel separation unit is reflected by the pixel separation unit, and the reflected incident light is returned to the photoelectric conversion unit, so that the quantum efficiency QE is improved and optical color mixing (crosstalk) is suppressed.

### CITATION LIST

### Patent Document

Patent Document 1: Japanese Patent Application Laid-Open No. 2017-191950

### SUMMARY OF THE INVENTION

### Problems to be Solved by the Invention

However, in the decrease of the quantum efficiency QE and the occurrence of optical color mixing due to long-wavelength light, components reflected by wiring of a wiring layer, an interface between a substrate and the wiring layer and the like are dominant. Therefore, in the technology (photoelectric conversion unit) disclosed in Patent Document 1, improvement in quantum efficiency QE and suppression of optical color mixing are insufficient.

An object of the present disclosure is to provide a light detection device and an electronic device capable of suppressing optical color mixing while improving quantum efficiency QE.

### Solutions to Problems

A light detection device according to the present disclosure includes (a) a substrate including a plurality of photoelectric conversion units, and (b) a wiring layer arranged on a side opposite to a light receiving surface of the substrate, in which (d) the wiring layer includes a reflection layer formed so as to overlap at least a part of the plurality of photoelectric conversion units in a stacking direction in which the substrate and the wiring layer are stacked, and (d) the reflection layer includes a plurality of recesses each including a corner cube-shaped portion in each of portions overlapping the photoelectric conversion units on a surface on a side of the photoelectric conversion units.

An electronic device according to the present disclosure includes a light detection device including (a) a substrate including a plurality of photoelectric conversion units, and (b) a wiring layer arranged on a side opposite to a light receiving surface of the substrate, in which (c) the wiring layer includes a reflection layer formed so as to overlap at least a part of the plurality of photoelectric conversion units in a stacking direction in which the substrate and the wiring layer are stacked, and (d) the reflection layer includes a plurality of recesses each including a corner cube-shaped portion in each of portions overlapping the photoelectric conversion units on a surface on a side of the photoelectric conversion units.

### BRIEF DESCRIPTION OF DRAWINGS

FIG. 1 is a diagram illustrating an overall configuration of a solid-state imaging device according to a first embodiment.

FIG. 2 is a diagram illustrating a circuit configuration of a pixel of the solid-state imaging device.

FIG. 3 is a diagram illustrating a cross-sectional configuration of the solid-state imaging device cut along line A-A in FIG. 1.

FIG. 4 is a diagram illustrating a cross-sectional configuration of the solid-state imaging device cut along line B-B in FIG. 3.

FIG. 5 is a diagram illustrating a configuration of a recess including a corner cube-shaped portion.

FIG. 6 is a diagram illustrating a cross-sectional configuration of a solid-state imaging device according to a variation cut at a position corresponding to line B-B in FIG. 3.

FIG. 7 is a diagram illustrating a cross-sectional configuration of the solid-state imaging device according to the variation cut at a position corresponding to line B-B in FIG. 3.

FIG. 8 is a diagram illustrating a cross-sectional configuration of a conventional solid-state imaging device.

FIG. 9 is a diagram illustrating a cross-sectional configuration of the solid-state imaging device according to the variation cut at a position corresponding to line B-B in FIG. 3.

FIG. 10 is a view illustrating a cross-sectional configuration of the solid-state imaging device according to the variation.

FIG. 11 is a diagram illustrating a cross-sectional configuration of the solid-state imaging device according to the variation cut along line C-C in FIG. 10.

FIG. 12 is a diagram illustrating a cross-sectional configuration of the solid-state imaging device according to the variation cut at a position corresponding to line B-B in FIG. 3.

FIG. 13 is a diagram illustrating a cross-sectional configuration of the solid-state imaging device according to the variation cut at a position corresponding to line B-B in FIG. 3.

FIG. 14 is a diagram illustrating a cross-sectional configuration of the solid-state imaging device according to the variation.

FIG. 15 is a diagram illustrating a cross-sectional configuration of the solid-state imaging device according to the variation.

FIG. 16 is a diagram illustrating a cross-sectional configuration of the solid-state imaging device according to the variation.

FIG. 17 is a diagram illustrating a cross-sectional configuration of the solid-state imaging device according to the variation cut at a position corresponding to line B-B in FIG. 3.

FIG. 18 is a diagram illustrating a cross-sectional configuration of the solid-state imaging device according to the variation cut at a position corresponding to line B-B in FIG. 3.

FIG. 19 is a diagram illustrating a cross-sectional configuration of the solid-state imaging device according to the variation.

FIG. 20 is a schematic configuration diagram of an electronic device according to a second embodiment.

### MODE FOR CARRYING OUT THE INVENTION

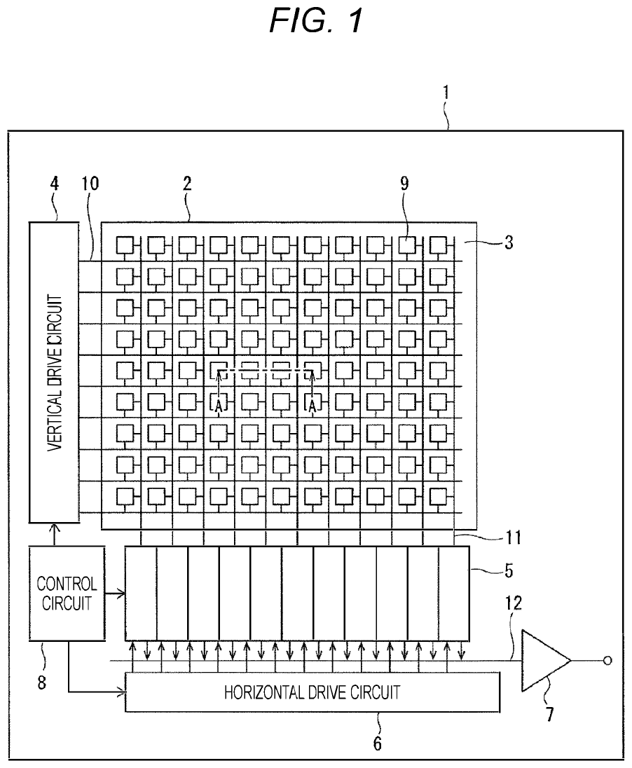

Hereinafter, an example of a light detection device and an electronic device according to an embodiment of the present disclosure will be described with reference to FIGS. 1 to 20. The embodiments of the present disclosure will be described in the following order. Note that, the present disclosure is not limited to the following examples. Furthermore, the effects described in the present specification are illustrative and not restrictive, and there may be additional effects.
1. First Embodiment: Solid-State Imaging Device
1-1 Overall Configuration of Solid-State Imaging Device
1-2 Circuit Configuration of Pixel
1-3 Configuration of Substantial Part
1-4 Variations
2. Second Embodiment: Application Example to Electronic Device

### 1. First Embodiment: Solid-State Imaging Device

### [1-1 Overall Configuration of Solid-State Imaging Device]

A solid-state imaging device 1 (in a broad sense, a “light detection device”) according to a first embodiment of the present disclosure will be described. FIG. 1 is a schematic configuration diagram illustrating an entire solid-state imaging device 1 according to the first embodiment.

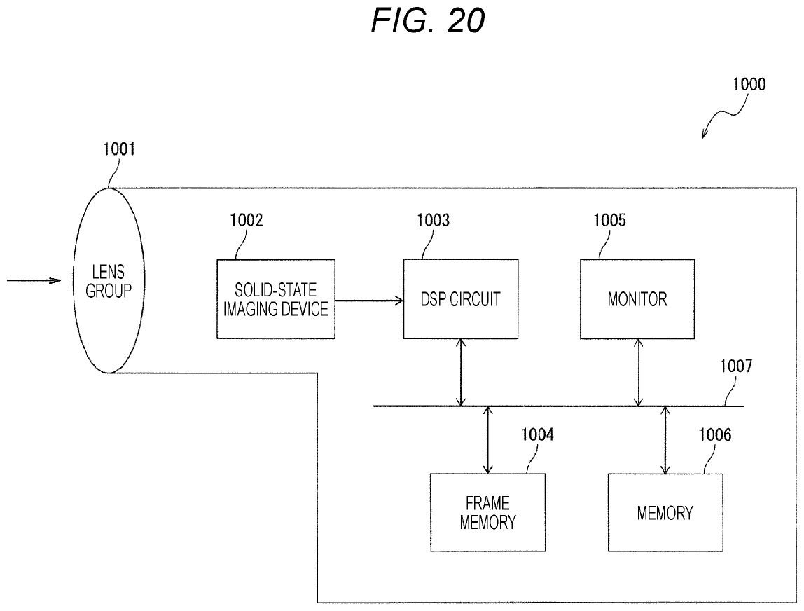

The solid-state imaging device 1 in FIG. 1 is a back-illuminated complementary metal oxide semiconductor (CMOS) image sensor. As illustrated in FIG. 20, the solid-state imaging device 1 (1002) captures image light (incident light) from a subject via a lens group 1001, converts an amount of the incident light an image of which is formed on an imaging surface into an electric signal in units of pixels, and outputs the same as a pixel signal.

As illustrated in FIG. 1, the solid-state imaging device 1 is provided with a substrate 2, a pixel region 3, a vertical drive circuit 4, a column signal processing circuit 5, a horizontal drive circuit 6, an output circuit 7, and a control circuit 8.

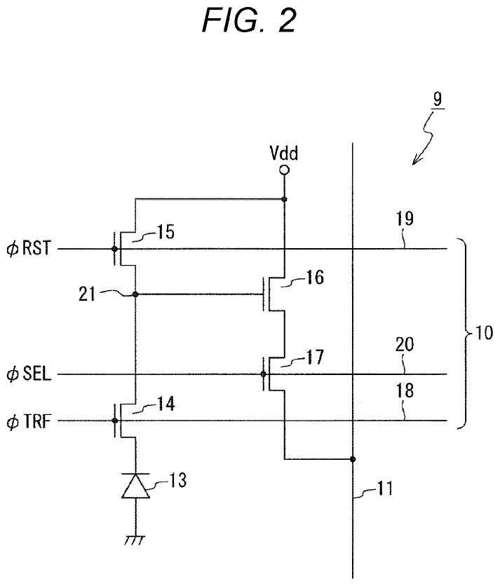

The pixel region 3 includes a plurality of pixels 9 regularly arrayed in a two-dimensional array on the substrate 2. The pixel 9 includes a photoelectric conversion unit 13 illustrated in FIGS. 2, 3, and 4, and a plurality of pixel transistors. As the plurality of pixel transistors, four transistors including a transfer transistor 14, a reset transistor 15, an amplification transistor 16, and a selection transistor 17 can be employed, for example. Furthermore, for example, they may be the transfer transistor 14, the reset transistor 15, and the amplification transistor 16 excluding the selection transistor 17.

The vertical drive circuit 4 includes, for example, a shift register, selects desired pixel drive wiring 10, supplies a pulse for driving the pixel 9 to the selected pixel drive wiring 10, and drives the pixels 9 in units of rows. That is, the vertical drive circuit 4 selectively scans each pixel 9 in the pixel region 3 sequentially in a vertical direction in units of rows, and supplies a pixel signal based on a signal charge generated in accordance with an amount of received light in the photoelectric conversion unit 13 of each pixel 9, to the column signal processing circuit 5 through a vertical signal line 11.

The column signal processing circuit 5 is arranged, for example, for each column of the pixels 9, and performs signal processing such as noise removal on signals output from the pixels 9 of one row for each pixel column. For example, the column signal processing circuit 5 performs signal processing such as correlated double sampling (CDS) for removing a fixed pattern noise unique to pixels, and analog-digital (AD) conversion.

The horizontal drive circuit 6 includes, for example, a shift register, sequentially outputs a horizontal scanning pulse to the column signal processing circuit 5, sequentially selects each of the column signal processing circuits 5, and causes each of the column signal processing circuits 5 to output the pixel signal subjected to the signal processing to a horizontal signal line 12.

The output circuit 7 performs signal processing on the pixel signals sequentially supplied from each of the column signal processing circuits 5 through the horizontal signal line 12, and outputs the same. As the signal processing, for example, buffering, black level adjustment, column variation correction, various types of digital signal processing and the like can be used.

The control circuit 8 generates a clock signal and a control signal serving as a reference of operations of the vertical drive circuit 4, the column signal processing circuit 5, the horizontal drive circuit 6 and the like on the basis of a vertical synchronization signal, a horizontal synchronization signal, and a master clock signal. Then, the control circuit 8 outputs the generated clock signal and control signal to the vertical drive circuit 4, the column signal processing circuit 5, the horizontal drive circuit 6 and the like.

### [1-2 Circuit Configuration of Pixel]

Next, a circuit configuration of the pixel 9 in FIG. 1 will be described. FIG. 2 is a diagram illustrating the circuit configuration of the pixel 9. FIG. 2 illustrates a case where the pixel 9 includes the photoelectric conversion unit 13, and four pixel transistors including the transfer transistor 14, the reset transistor 15, the amplification transistor 16, and the selection transistor 17. As the transfer transistor 14, the reset transistor 15, the amplification transistor 16, and the selection transistor 17, an N-channel MOS transistor can be employed, for example. Furthermore, as for the pixel 9, for example, three lines of drive wiring including a transfer line 18, a reset line 19, and a selection line 20 are commonly provided as the pixel drive wiring 10 for the pixels 9 of the same row. One end of each of the transfer line 18, the reset line 19, and the selection line 20 is connected to an output end corresponding to each row of the vertical drive circuit 4 in units of rows.

In the photoelectric conversion unit 13, an anode electrode is grounded and a cathode electrode is connected to a gate electrode of the amplification transistor 16 via the transfer transistor 14. Then, the photoelectric conversion unit 13 generates the signal charge corresponding to an amount of incident light 33. A node connected to the gate electrode of the amplification transistor 16 is referred to as a floating diffusion unit (FD unit) 21.

The transfer transistor 14 is connected between the cathode electrode of the photoelectric conversion unit 13 and the FD unit 21. A transfer pulse φTRF in which a high level (for example, Vdd) is active (hereinafter also referred to as “High active”) is applied to a gate electrode of the transfer transistor 14 via the transfer line 18. When the transfer pulse φTRF is applied, the transfer transistor 14 is turned on and transfers the signal charge generated by the photoelectric conversion unit 13 to the FD unit 21.

A drain electrode and a source electrode of the reset transistor 15 are connected to a pixel power supply Vdd and the FD unit 21, respectively. Prior to the transfer of the signal charge from the photoelectric conversion unit 13 to the FD unit 21 by the transfer transistor 14, a High active reset pulse PRST is applied to a gate electrode of the reset transistor 15 via the reset line 19. When the reset pulse φRST is applied, the reset transistor 15 is turned on and discharges the charge accumulated in the FD unit 21 to the pixel power supply Vdd, thereby resetting the FD unit 21.

The gate electrode and a drain electrode of the amplification transistor 16 are connected to the FD unit 21 and the pixel power supply Vdd, respectively. Then, the amplification transistor 16 outputs potential of the FD unit 21 after being reset by the reset transistor 15 as a reset signal (reset level) Vreset. Furthermore, the amplification transistor 16 outputs the potential of the FD unit 21 after the transfer transistor 14 transfers the signal charge as a light accumulation signal (signal level) Vsig.

In the selection transistor 17, a drain electrode is connected to a source electrode of the amplification transistor 16, and a source electrode is connected to the vertical signal line 11. A High active selection pulse φSEL is applied to a gate electrode of the selection transistor 17 via the selection line 20. When the selection pulse φSEL is applied, the selection transistor 17 is turned on to put the pixel 9 into a selected state and relays the signal output from the amplification transistor 16 to the vertical signal line 11.

### [1-3 Configuration of Substantial Part]

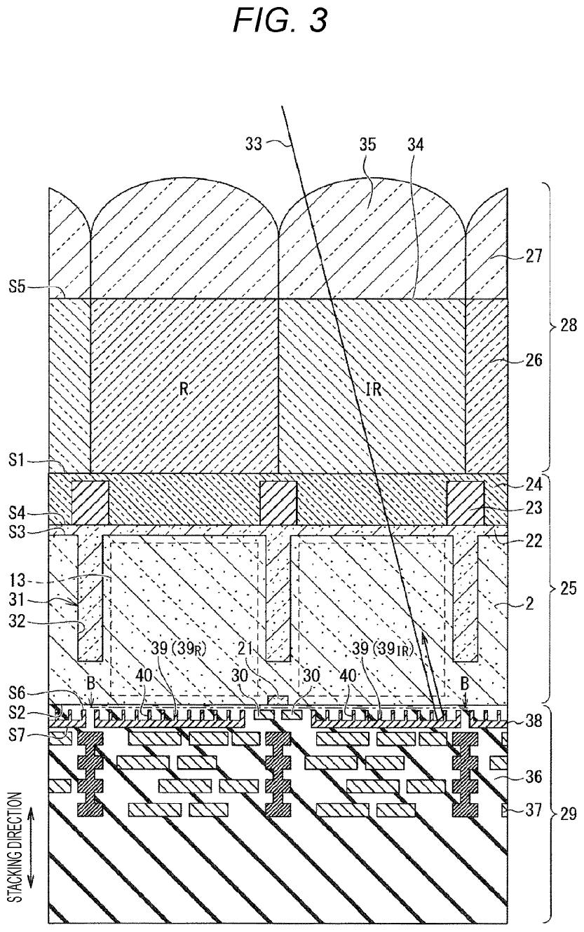

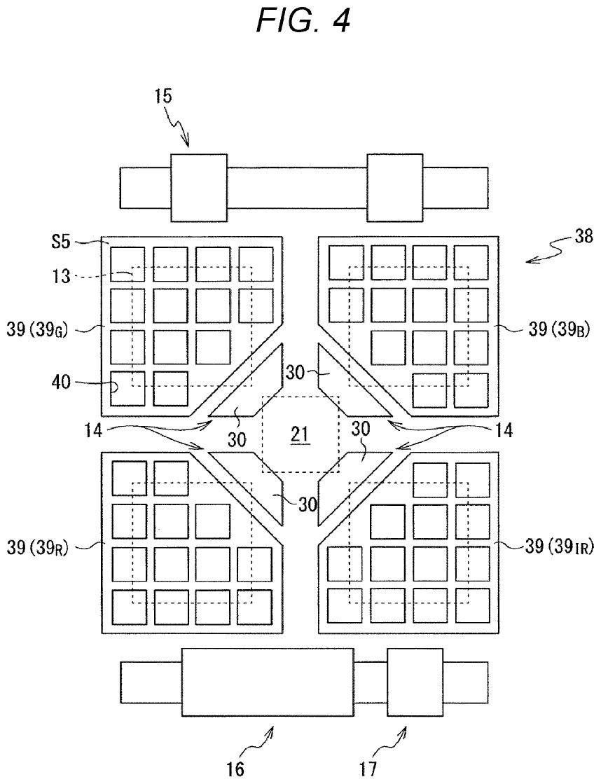

Next, a detailed structure of the solid-state imaging device 1 in FIG. 1 will be described. FIG. 3 is a diagram illustrating a cross-sectional configuration of the solid-state imaging device 1 cut along line A-A in FIG. 1. FIG. 4 is a diagram illustrating a cross-sectional configuration of the solid-state imaging device 1 cut along line B-B in FIG. 3. Note that, thane interlayer insulating film 36 is not illustrated in FIG. 4 to make a configuration of a reflection plate 39 apparent.

As illustrated in FIG. 3, the solid-state imaging device 1 is provided with a light receiving layer 25 formed by stacking the substrate 2, an insulating film 22, a light shielding film 23, and a planarization film 24 in this order. Furthermore, a light condensing layer 28 in which a color filter layer 26 and a microlens layer 27 are stacked in this order is formed on a surface on the planarization film 24 side (hereinafter, also referred to as a “back surface S1”) of the light receiving layer 25. Moreover, a wiring layer 29 is stacked on a surface on the substrate 2 side (hereinafter, also referred to as a “front surface S2”) of the light receiving layer 25. That is, it can be said that the wiring layer 29 is arranged on the side opposite to the back surface S3 (light-receiving surface) of the substrate 2.

The substrate 2 includes, for example, a semiconductor substrate of silicon (Si), and forms the pixel region 3. In the pixel region 3, a plurality of pixels 9 each including the photoelectric conversion unit 13, and four pixel transistors including the transfer transistor 14, the reset transistor 15, the amplification transistor 16, and the selection transistor 17 is arranged in a two-dimensional array. The photoelectric conversion unit 13 includes a p-type semiconductor region formed on the front surface S2 side of the substrate 2 and an n-type semiconductor region formed on the back surface S3 side (light receiving surface side) and forms a photodiode by pn junction. Therefore, each of the photoelectric conversion units 13 generates the signal charge corresponding to the amount of incident light on the photoelectric conversion unit 13, and accumulates the generated signal charge in the n-type semiconductor region. As illustrated in FIG. 4, the transfer transistor 14 includes the FD unit 21 and a transfer gate electrode 30. The FD unit 21 is formed in a central portion of a group including four photoelectric conversion units 13 of two rows by two columns in plan view (refer to FIG. 4), at a position between a bottom surface of a trench 32 in the substrate 2 and the wiring layer 29 in side view (refer to FIG. 2). Furthermore, the transfer gate electrode 30 is formed at a position slightly outside the central portion of the FD unit 21 in plan view (refer to FIG. 4) and between the substrate 2 and the wiring 37 in the wiring layer 29 in side view (refer to FIG. 2). Furthermore, the reset transistor 15, the amplification transistor 16, and the selection transistor 17 excluding the transfer transistor 14 are formed for each of the four photoelectric conversion units 13 sharing the FD unit 21.

Furthermore, a pixel separation unit 31 is formed between adjacent photoelectric conversion units 13. The pixel separation unit 31 is formed into a lattice shape so as to surround the periphery of each of the photoelectric conversion units 13. The pixel separation unit 31 includes a bottomed trench 32 extending from the back surface S3 side of the substrate 2 toward the surface on the opposite side. That is, the trench 32 does not penetrate the substrate 2, and the bottom surface thereof is formed in the substrate 2. Since the trench 22 does not penetrate the substrate 2, elements and contacts can be arranged in a region between the bottom of the pixel separation unit 31 and the wiring layer 29. FIG. 3 illustrates a case where the FD unit 21 is arranged in the region between the bottom of the pixel separation unit 21 and the wiring layer 20.

The trench 32 is formed into a lattice shape in such a manner that an inner side surface and a bottom surface form an outer shape of the pixel separation unit 31. Furthermore, the insulating film 22 that covers the back surface S3 side of the substrate 2 is embedded inside the trench 32. As a material of the insulating film 22, for example, a material having a refractive index different from that of a material (Si: refractive index 3.9) of the substrate 2 can be employed. Examples of the material include, for example, a silicon oxide (SiO₂: refractive index 1.5) and a silicon nitride (SiN: refractive index 2.0). Therefore, by increasing a difference between the refractive index of the photoelectric conversion unit 13 and the refractive index of the insulating film 22, a sufficient reflection characteristic can be obtained at an interface between the photoelectric conversion unit 13 and the pixel separation unit 31, the incident light 33 incident on the photoelectric conversion unit 13 can be prevented from being transmitted through the pixel separation unit 31 and leaking to the adjacent photoelectric conversion unit 13 side, and optical color mixing can be suppressed. Furthermore, the adjacent photoelectric conversion units 13 can be electrically separated from each other, and leakage of the signal charge accumulated in the photoelectric conversion unit 13 to the adjacent photoelectric conversion unit 13 side can be suppressed.

The insulating film 22 continuously covers an entire back surface S3 of the substrate 2 and the inside of the trench 32 in such a manner that the signal charge of the photoelectric conversion unit 13 does not leak. Furthermore, the light shielding film 23 is formed into a lattice shape that opens the light receiving surface side of each of a plurality of photoelectric conversion units 13, on a part on the back surface S4 side of the insulating film 22 so as to prevent light from leaking into adjacent pixels 9. Furthermore, the planarization film 24 continuously covers an entire back surface S4 side of the insulating film 22 in such a manner that the back surface S1 of the light receiving layer 25 becomes a flat surface.

The color filter layer 26 includes a plurality of color filters 34 formed on the back surface S1 side of the planarization film 24 (that is, also referred to as the back surface S3 side of the substrate 2) and arranged corresponding to the photoelectric conversion units 13. The plurality of color filters 34 includes a plurality of types of color filters that transmit light of a predetermined wavelength (for example, infrared light, red light, green light, and blue light). Therefore, each of the plurality of color filters 34 transmits light of a predetermined wavelength for each type of the color filters 34, and causes the transmitted light to be incident on the corresponding photoelectric conversion unit 13. As the array pattern of the color filters 34, for example, an array based on the Bayer array in which one of the two green light color filters in the Bayer array is replaced with a color filter that transmits infrared light can be employed.

Note that, although an example in which the color filter that transmits infrared light, red light, green light, or blue light is used as the color filter 34 is described in the first embodiment, other configurations can be employed. For example, a color filter that transmits light in all wavelength bands may be used.

The microlens layer 27 is formed on a back surface S5 side of the color filter layer 26, and includes a plurality of microlenses 35 arranged corresponding to the photoelectric conversion units 13. Therefore, each of the microlenses 35 condenses image light (incident light 33) from a subject, and allows the condensed incident light 33 to efficiently enter the corresponding photoelectric conversion unit 13 via the color filter 34.

The wiring layer 29 is formed on the front surface S2 side of the substrate 2, and includes the interlayer insulating film 36 and a plurality of layers of wiring 37 stacked with the interlayer insulating film 36 interposed therebetween. Then, the wiring layer 29 drives the pixel transistor forming each pixel 9 via the plurality of layers of wiring 37.

Furthermore, a reflection layer 38 is formed on the substrate 2 side of the wiring layer 29. An entire reflection layer 38 is located in the wiring layer 29. Therefore, for example, unlike a method of arranging a portion on the substrate 2 side of the reflection layer 38 in the substrate 2, a volume of the photoelectric conversion unit 13 is not reduced, and reduction in the number of saturated electrons of the photoelectric conversion unit 13 can be suppressed. Furthermore, the reflection layer 38 includes a plurality of reflection plates 39 formed between an interface between the wiring layer 29 and the substrate 2 and the wiring 37 and arranged corresponding to the photoelectric conversion units 13. That is, as illustrated in FIG. 4, one reflection plate 39 is formed for one photoelectric conversion unit 13. Therefore, the reflection layer 38 is formed so as to overlap at least a part of the plurality of photoelectric conversion units 13 in a stacking direction in which the substrate 2 and the wiring layer 29 are stacked. In FIG. 4, the reflection plate 39 on which the infrared light is incident by a light transmitting function of the color filter 34 is represented by “39_{IR}”, and similarly, the reflection plate 39 on which red light is incident is represented by “39_{R}”, the reflection plate 39 on which green light is incident is represented by “39_{G}”, and the reflection plate 39 on which blue light is incident is represented by “39_{B}”. That is, FIG. 4 illustrates a case where the color filter 34 that transmits infrared light is arranged on the light receiving surface side of the reflection plate 39_{IR}, the color filter 34 that transmits red light is arranged on the light receiving surface side of the reflection plate 39_{R}, the color filter 34 that transmits green light is arranged on the light receiving surface side of the reflection plate 39_{G}, and the color filter 34 that transmits blue light is arranged on the light receiving surface side of the reflection plate 39_{B}.

As illustrated in FIG. 4, a planar shape of the reflection plate 39 is a pentagon obtained after a corner on the transfer gate electrode 30 side of a quadrangle slightly larger than the photoelectric conversion unit 13 is omitted. Therefore, the transfer gate electrode 30 is arranged at a site corresponding to the omitted corner. That is, the reflection plate 39 is arranged at a position not overlapping the gate electrode (transfer gate electrode 30) of the transistor formed on the surface on the side opposite to the back surface S3 (light receiving surface) of the substrate 2 in the stacking direction of the substrate 2 and the wiring layer 29. Therefore, the reflection plate 39 can be arranged at the same depth as the transfer gate electrode 30, and the contact connecting the substrate 2 and the wiring 37 can be shortened.

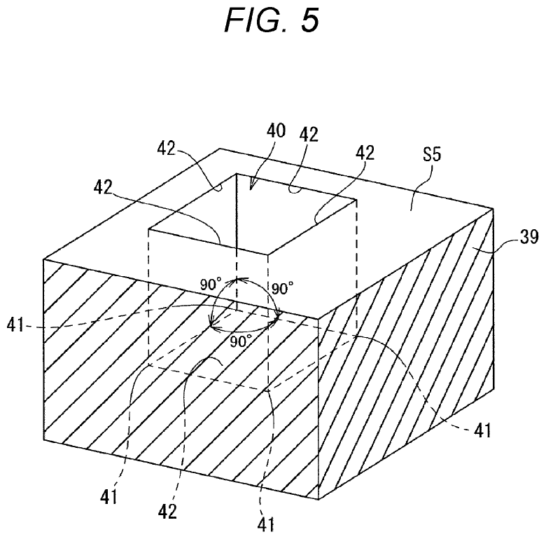

Furthermore, a plurality of recesses 40 including a corner cube-shaped portion is arranged in a two-dimensional array on a surface (hereinafter, also referred to as a “back surface S6”) on the photoelectric conversion unit 13 side of the reflection plate 39. Therefore, the reflection layer 38 has a structure including a plurality of recesses 40 in each portion overlapping the photoelectric conversion unit 13 on the surface on the photoelectric conversion unit 13 side. Note that, in FIG. 3, the number of recesses 40 arranged in a row direction is larger than four, but in FIG. 4, a case where the recesses 40 are arranged in a two-dimensional array of four rows by four columns is illustrated for the sake of simplicity of description. Examples of the recess 40 include, for example, a quadrangular prism-shaped recess in which each of corners 41 at four corners forms a corner cube including three reflection planes 42 and a vertex at which the three reflection planes 42 intersect as illustrated in FIG. 5. FIG. 5 illustrates a case where a recess having sides of an internal dimension of the same length is used as the quadrangular prism-shaped recess. Therefore, when light is incident, the recess 40 performs retroreflection to specularly reflect the incident light between the reflection planes 42 and return the specularly reflected light in an incident direction again.

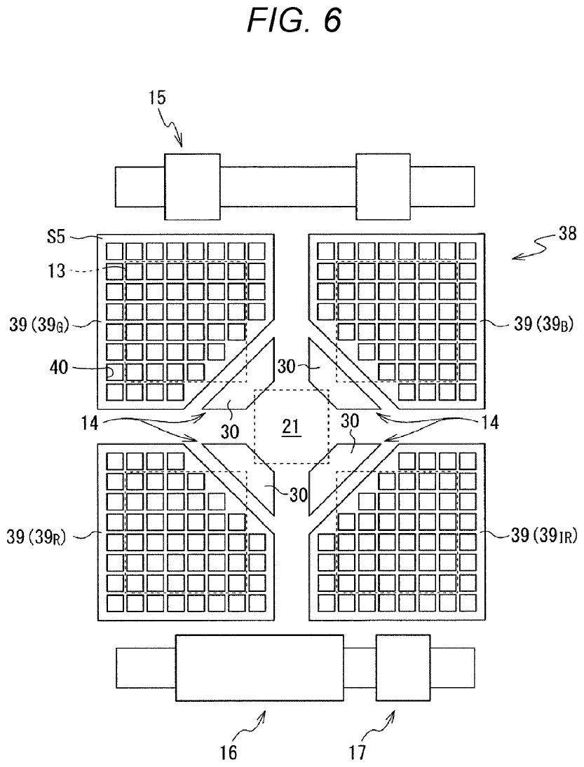

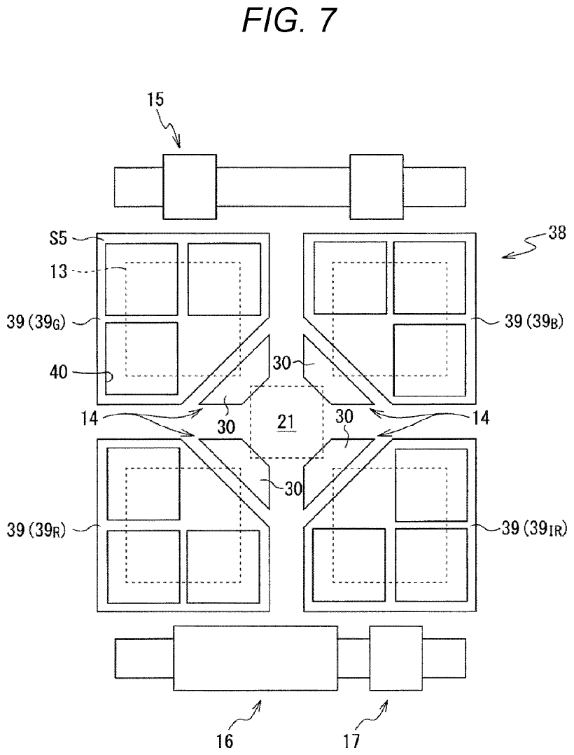

Note that, a size of the recess 40 may be any size as illustrated in FIGS. 6 and 7 as long as the recess 40 can be formed. FIG. 6 illustrates a case where the recess 40 is larger than the recess 40 in FIG. 5. Furthermore, FIG. 7 illustrates a case where the recess 40 is smaller than the recess 40 in FIG. 5. Furthermore, the number of recesses 40 arranged on the back surface S6 of each reflection plate 39 may be any number. Furthermore, although FIG. 5 illustrates an example in which the three reflection planes 42 form an angle of 90° with each other, there is no limitation, and the angle may be different from 90° as long as retroreflection of light is possible.

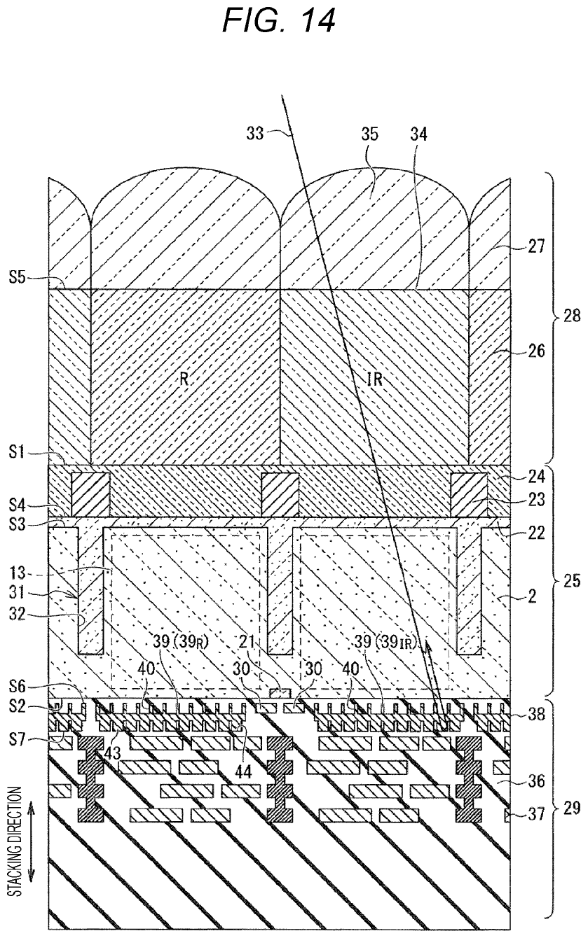

A surface on the side opposite to the photoelectric conversion unit 13 of the reflection plate 39 (hereinafter also referred to as a “front surface S7”) is a flat surface parallel to the front surface S2 of the substrate 2. Therefore, for example, as compared with a case where the front surface S7 of the reflection plate 39 includes a protrusion 43 illustrated in FIG. 14, a distance between the interface between the wiring layer 29 and the substrate 2 and the wiring 37 can be shortened, and the contact that connects the substrate 2 and the wiring 37 can be shortened.

A material of the reflection layer 38 is only required to be, for example, any material that can reflect the incident light 33 (red light, blue light, green light, and infrared light) transmitted through the color filter 34. For example, polysilicon (p-Si), tungsten (W), and copper (Cu) can be employed. Here, generally, polysilicon (p-Si) is used as a material of a gate electrode of the pixel transistor, tungsten (W) is used as a material of the light shielding film 23, and copper (Cu) is used as a material of the wiring 37. Therefore, by employing polysilicon (p-Si), tungsten (W), or copper (Cu) as the material of the reflection layer 38, the reflection layer 38 can be relatively easily formed by using existing equipment for manufacturing the solid-state imaging device.

In the solid-state imaging device 1 having the above-described configuration, light is emitted from the back surface S3 side of the substrate 2 (the back surface S1 side of the light receiving layer 25), the emitted light is transmitted through the microlens 35 and the color filter 34 (waveguide), and the transmitted light is photoelectrically converted by the photoelectric conversion unit 13 to generate the signal charge. Then, the generated signal charge is output as the pixel signal by the vertical signal line 11 in FIG. 1, formed by using the wiring 37, via the pixel transistor formed on the front surface S2 side of the substrate 2.

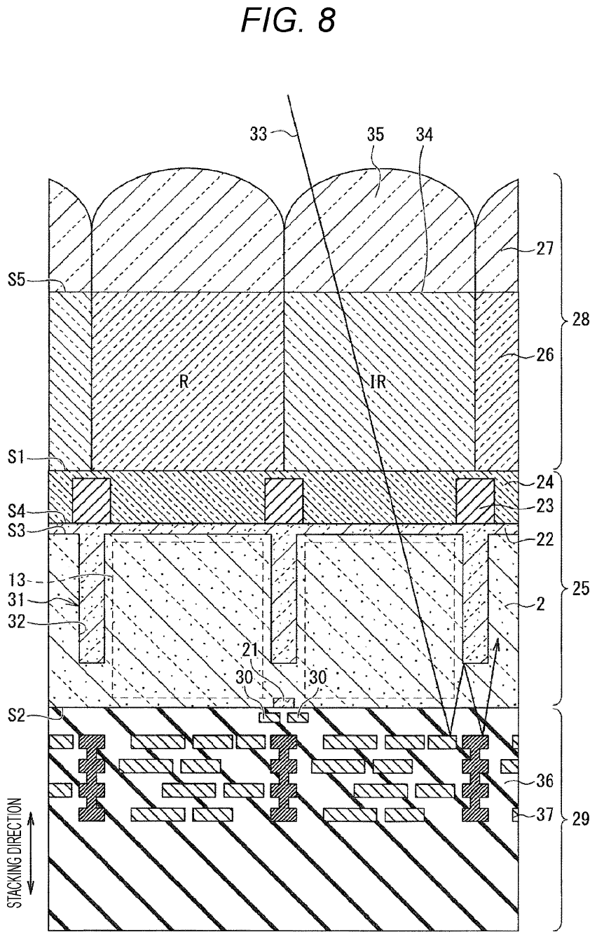

Here, long-wavelength light (infrared light) is poorly absorbed by silicon (Si). Therefore, for example, in a case where the reflection layer 38 is not present, as illustrated in FIG. 8, when long-wavelength light (infrared light) out of the incident light 33 is incident on the photoelectric conversion unit 13 of the solid-state imaging device 1, the incident long-wavelength light (infrared light) passes through the photoelectric conversion unit 13, is reflected by the wiring 37 of the wiring layer 29, and passes through a portion closer to the wiring 37 than the bottom of the pixel separation unit 31 to exit to the adjacent photoelectric conversion unit 13, so that there is a possibility that quantum efficiency QE decreases. Furthermore, there is a possibility that optical color mixing (crosstalk) occurs because the incident light 33 that exits is detected by the adjacent photoelectric conversion unit 13.

In contrast, in the first embodiment, as illustrated in FIG. 2, the wiring layer 29 includes the reflection layer 38 formed so as to overlap at least a part of the plurality of photoelectric conversion units 13 in the stacking direction in which the substrate 2 and the wiring layer 29 are stacked. Then, the reflection layer 38 includes a plurality of recesses 40 including the corner cube-shaped portion in each portion overlapping the photoelectric conversion unit 13 on the surface on the photoelectric conversion unit 13 side. Therefore, out of the incident light 33 that has passed through the photoelectric conversion unit 13, the incident light 33 that hits the corner cube-shaped portion of the recess 40 of the reflection layer 38 is retroreflected by the corner cube-shaped portion, returns in a direction along the incident direction, and is incident on the original photoelectric conversion unit 13 again. Therefore, the reflected light can be prevented from entering the adjacent pixel 9, and optical color mixing can be prevented. Furthermore, by incidence on the original photoelectric conversion unit 13, the reflected light can be absorbed by the original photoelectric conversion unit 13, and the quantum efficiency QE can be improved. Therefore, it is possible to provide the solid-state imaging device 1 capable of suppressing optical color mixing while improving the quantum efficiency QE.

### [1-4 Variation]

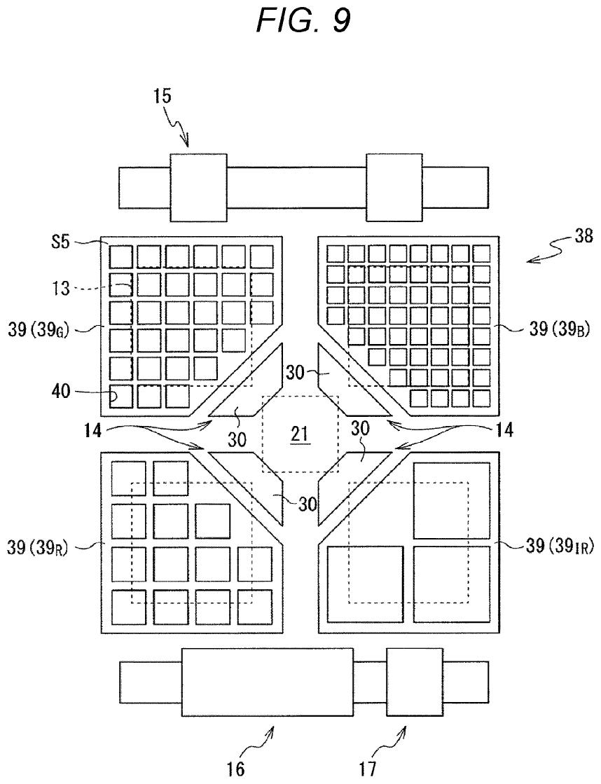

(1) Note that, although the example in which the recess 40 has the same size in all the reflection plates 39 is described in the first embodiment, other configurations may be employed. For example, as illustrated in FIG. 9, the size of the recess 40 may be set for each type (a color filter that transmits infrared light, a color filter that transmits red light, a color filter that transmits green light, and a color filter that transmits blue light) of the color filter 34 corresponding to the reflection plate 39 on which the recess 40 is formed. That is, the size of the recess 40 may be determined according to a wavelength of light transmitted through the color filter 34 (refer to FIG. 2) and enters the reflection plate 39. FIG. 9 illustrates a case where the size of the recess 40 (a length of each side of the recess 40) is increased with the reflection plate 39 in which the wavelength of the incident light is longer. As an example, suppose that the size of the recess 40 of the reflection plate 39_{IR} on which infrared light is incident>the size of the recess 40 of the reflection plate 39_{R} on which red light is incident>the size of the recess 40 of the reflection plate 39_{G} on which green light is incident>the size of the recess 40 of the reflection plate 39; on which blue light is incident is satisfied. Therefore, it is possible to more appropriately retroreflect the incident light 33 transmitted through the photoelectric conversion unit 13 hit the corner cube-shaped portion of the recess 40 to the original photoelectric conversion unit 13.

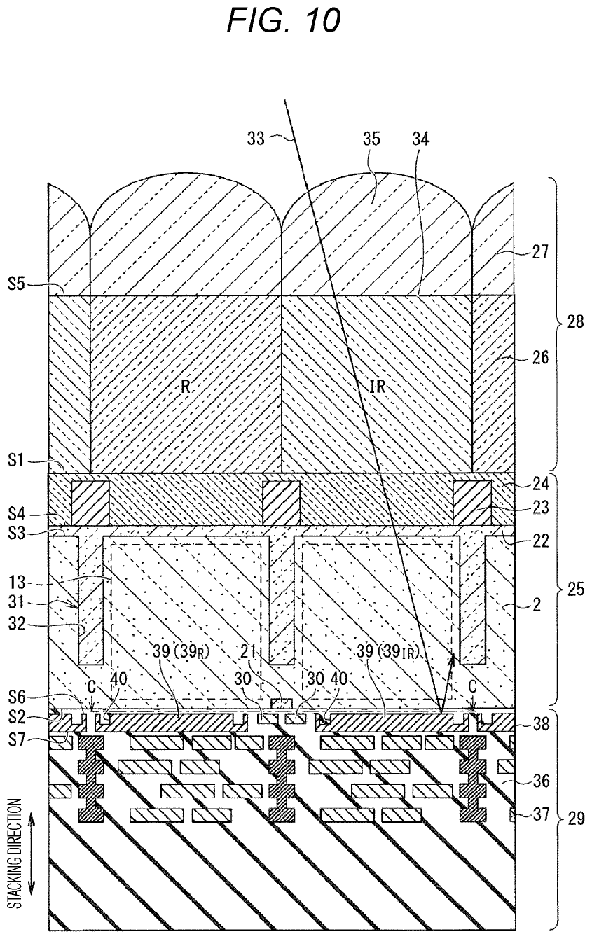

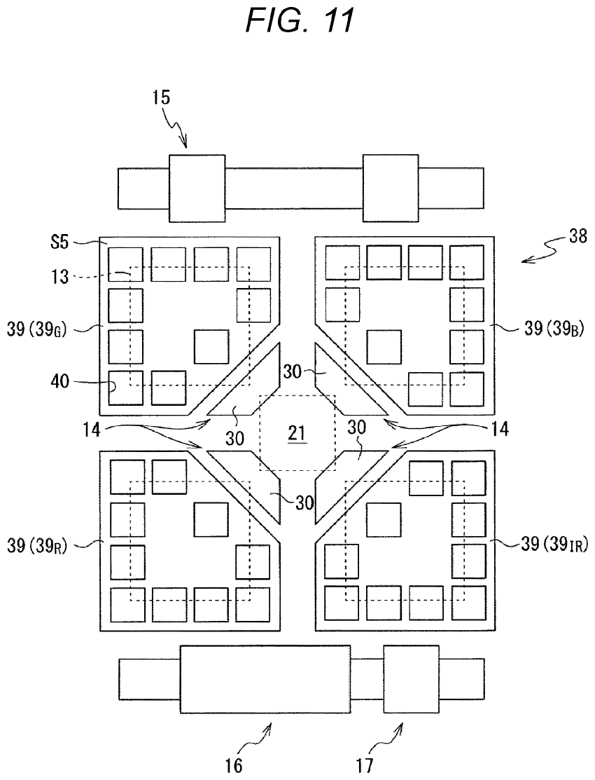

(2) Furthermore, although the example in which the recesses 40 are uniformly arranged in each portion on the back surface S6 of the reflection plate 39 is illustrated in the first embodiment, other configurations can also be employed. For example, as illustrated in FIGS. 10 and 11, a configuration in which the recesses 40 are formed only on an outer edge of the back surface S6 of the reflection plate 39, and the recesses 40 are not formed at the center of the back surface S6 is also possible. Therefore, since the center of the back surface S6 of the reflection plate 39 becomes a flat surface parallel to the back surface S3 of the substrate 2, the incident light 33 transmitted through the photoelectric conversion unit 13 is specularly reflected, and the reflected light is returned to the original photoelectric conversion unit 13 at a reflection angle equal to the incident angle. Furthermore, since the specular reflection is performed at the center of the back surface S6 of the reflection plate 39, the reflected light does not pass between the bottom of the pixel separation unit 31 and the wiring 37, hits a surface on the photoelectric conversion unit 13 side of the pixel separation unit 31 to be specularly reflected, and is returned to the original photoelectric conversion unit 13. Therefore, as in the case where the recesses 40 are uniformly arranged in each portion on the back surface S6 of the reflection plate 39, it is possible to suppress optical color mixing while improving the quantum efficiency QE.

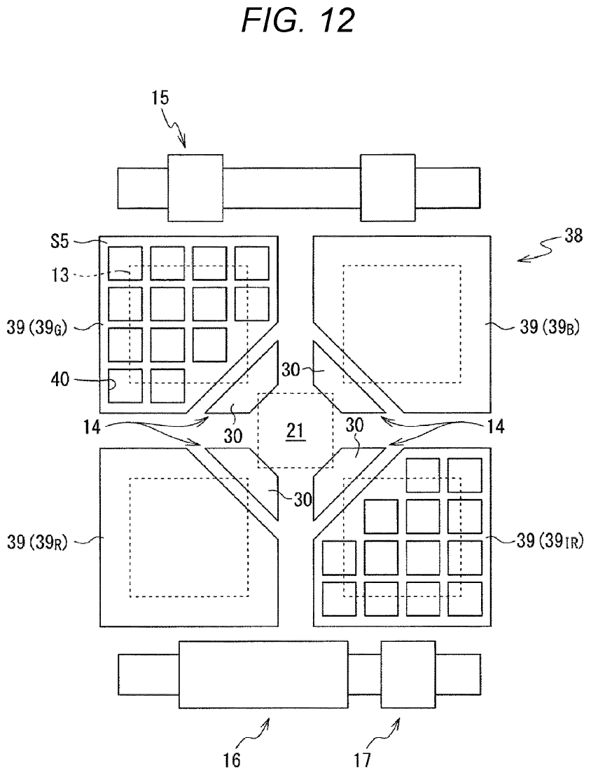

(3) Furthermore, although the example in which all of the plurality of reflection plates 39 forming the reflection layer 38 include the recesses 40 is described in the first embodiment, other configurations can also be employed. For example, as illustrated in FIG. 12, a configuration in which only a part of the reflection plates 39 includes the recesses 40, and the remaining reflection plates 39 do not include the recess 40 is also possible. FIG. 12 illustrates a case where only the reflection plate 39_{IR} on which infrared light is incident and the reflection plate 39_{G} on which green light is incident includes the recesses 40, and the reflection plate 39_{R} on which red light is incident and the reflection plate 39; on which blue light is incident does not include the recess 40.

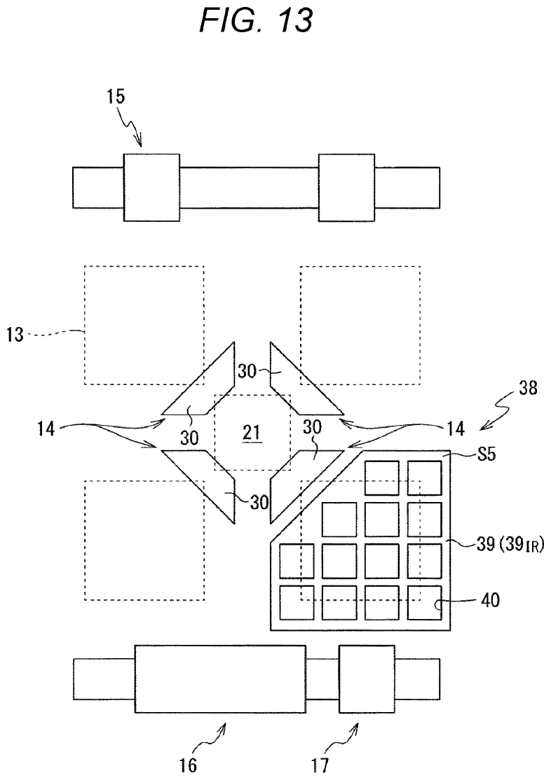

(4) Furthermore, although the example in which the reflection plate 39 is arranged corresponding to each of all the photoelectric conversion units 13 is described in the first embodiment, other configurations can also be employed. For example, as illustrated in FIG. 13, the reflection plate 39 may be arranged so as to correspond to only a part of the photoelectric conversion units 13. FIG. 13 illustrates a case in which the reflection plate 39_{IR} is arranged only for the photoelectric conversion unit 13 on which infrared light (long-wavelength light) is incident. Therefore, the reflection plate 39 corresponding to the photoelectric conversion unit 13 to which infrared light (long-wavelength light) is not incident can be omitted, and a design can be simplified.

(5) Furthermore, although an example in which the back surface S6 of the reflection plate 39 includes a plurality of recesses 40 and the surface S7 is made a flat surface is described in the first embodiment, other configurations can also be employed. For example, as illustrated in FIG. 14, a plurality of quadrangular prism-shaped protrusions 43 may be arranged in a two-dimensional array on the front surface S7 of the reflection plate 39. Therefore, the reflection layer 38 has a structure including a plurality of quadrangular prism-shaped protrusions 43 on the surface on the side opposite to the substrate 2. FIG. 14 illustrates a case where a protrusion having sides of the same length (width, depth, and height) is used as the quadrangular prism-shaped protrusion 43. The length of each side of the protrusion 43 is the same as the length of each side of the internal dimension of the recess 40. Therefore, a quadrangular prism-shaped recess 44 including a corner cube-shaped portion is formed in a portion in contact with the protrusion 43 of the interlayer insulating film 36. That is, in the interlayer insulating film 36 on the front surface S7 side of the reflection plate 39, a plurality of recesses 44 including a corner cube-shaped portion is formed in a two-dimensional array, similarly to the recesses 40 of the reflection plate 39. Therefore, the incident light 33 transmitted through the reflection plate 39 out of the incident light 33 that hits the reflection layer 38 can be retroreflected by the corner cube-shaped portion of the recess 44, and the reflected light can be absorbed by the original photoelectric conversion unit 13 to further improve the quantum efficiency QE.

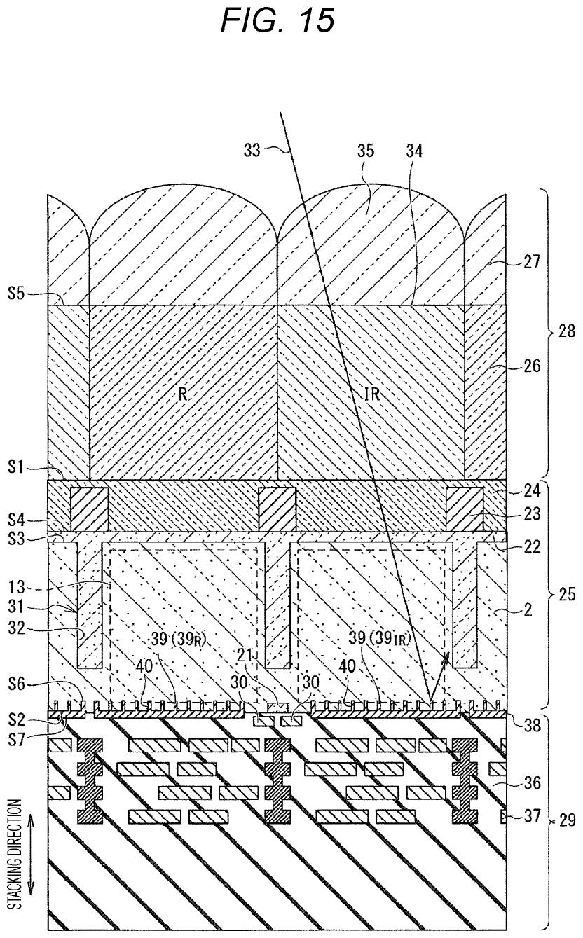

(6) Furthermore, although the example in which an entire reflection plate 39 is located in the wiring layer 29 is described in the first embodiment, other configurations can also be employed. For example, as illustrated in FIG. 15, a part on the substrate 2 side of the reflection layer 38 may be located in the substrate 2, and a part on a side opposite to the substrate 2 may be located in the wiring layer 29. Therefore, the distance between the interface between the wiring layer 29 and the substrate 2 and the wiring 37 can be shortened, and the contact connecting the substrate 2 and the wiring 37 can be shortened. Furthermore, the gap between the reflection plate 39 and the pixel separation unit 31 can be made small, and the reflected light reflected by the reflection plate 39 can be suppressed from passing through the gap to exit to the adjacent photoelectric conversion unit 13.

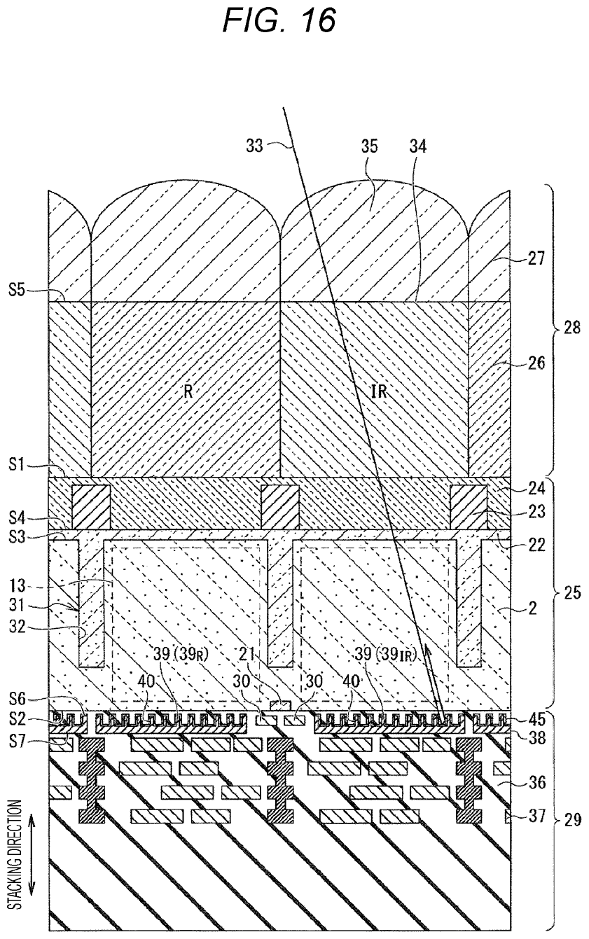

(7) Furthermore, although the example in which the inner surface of the recess 40 is in direct contact with the interlayer insulating film 36 is described in the first embodiment, other configurations can also be employed. For example, as illustrated in FIG. 16, a low refractive index film 45 that covers the inner surface of the recess 40 may be included. FIG. 16 illustrates a case where the low refractive index film 45 continuously covers the inner surface of the recess 40 and the back surface S6 of the reflection plate 39. As a material of the low refractive index film 45, for example, a material having a lower reflectivity than that of a material of a layer, a film and the like with which the inner surface of the recess 40 is in contact via the low refractive index film 45 can be employed. In FIG. 16, a material having a lower reflectivity than that of the material of the interlayer insulating film 36 is used as the material of the low refractive index film 45. Therefore, the reflectivity at the interface between the interlayer insulating film 36 and the recess 40 can be improved, and the quantum efficiency QE can be further improved.

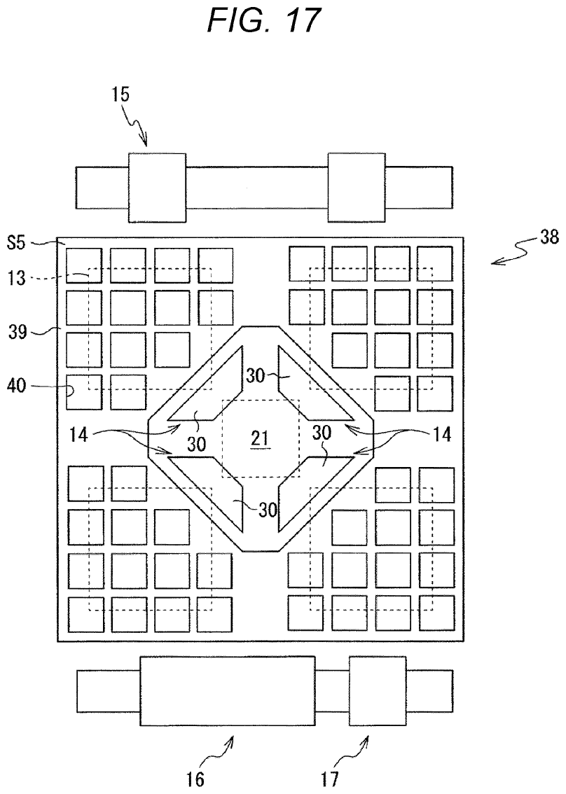

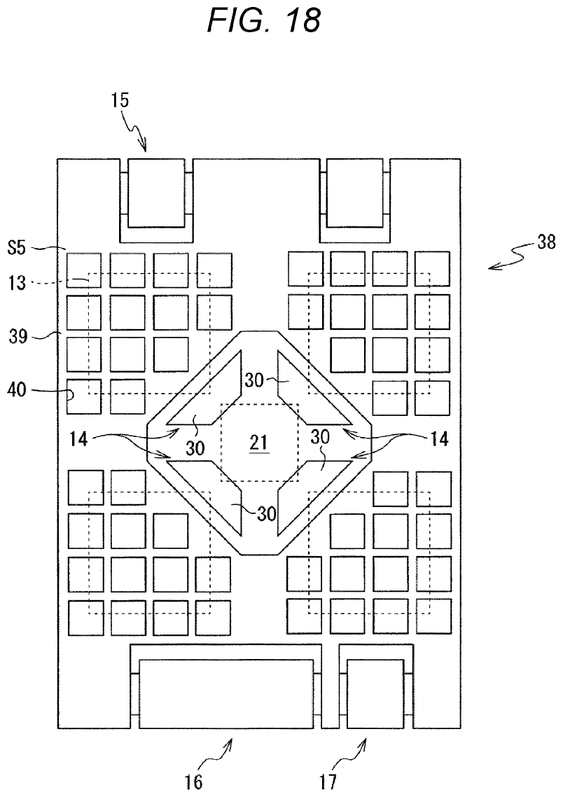

(8) Furthermore, although the example in which one reflection plate 39 is formed for one photoelectric conversion unit 13 is described in the first embodiment, other configurations can also be employed. For example, as illustrated in FIG. 17, one reflection plate 39 may be formed for four photoelectric conversion units 13. Furthermore, for example, as illustrated in FIG. 18, one reflection plate 39 may be formed for all the photoelectric conversion units 13. That is, one reflection plate 39 may form the reflection layer 38.

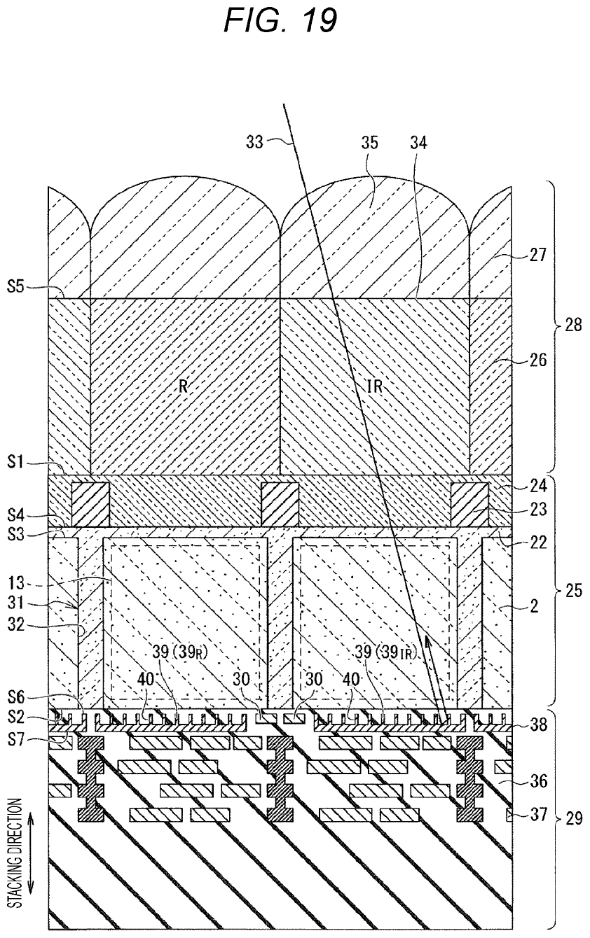

(9) Furthermore, although the example in which the pixel separation unit 31 includes the bottom in the substrate 2 is described in the first embodiment, other configurations can also be employed. For example, as illustrated in FIG. 19, the pixel separation unit 31 may penetrate the substrate 2 and include the bottom at the interface between the substrate 2 and the wiring layer 29. Therefore, the gap between the reflection plate 39 and the pixel separation unit 31 can be made small, and possibility that the reflected light reflected by the reflection plate 39 passes through the gap to exit to the adjacent photoelectric conversion unit 13 may be reduced.

(10) Furthermore, the present technology is applicable to any light detection device including not only the above-described solid-state imaging device as an image sensor but also a ranging sensor also referred to as a time of flight (ToF) sensor that measures a distance and the like. The ranging sensor is a sensor that emits irradiation light toward an object, detects reflected light that is the irradiation light reflected by a surface of the object to return, and calculates a distance to the object on the basis of a flight time from the emission of the irradiation light to the reception of the reflected light. As a light receiving pixel structure of the ranging sensor, the structure of the pixel 9 described above may be employed.

### 2. Second Embodiment: Application Example to Electronic Device

The technology (present technology) according to the present disclosure may be applied to various electronic devices.

FIG. 20 is a diagram illustrating an example of a schematic configuration of an imaging device (video camera, digital still camera and the like) as an electronic device to which the present disclosure is applied.

As illustrated in FIG. 20, an imaging device 1000 is provided with a lens group 1001, a solid-state imaging device 1002 (the solid-state imaging device 1 according to the first embodiment), a digital signal processor (DSP) circuit 1003, a frame memory 1004, a monitor 1005, and a memory 1006. The DSP circuit 1003, the frame memory 1004, the monitor 1005, and the memory 1006 are connected to each other via a bus line 1007.

The lens group 1001 guides incident light (image light) from a subject to the solid-state imaging device 1002 to form an image on a light receiving surface (pixel region) of the solid-state imaging device 1002.

The solid-state imaging device 1002 includes the above-described CMOS image sensor of the first embodiment. The solid-state imaging device 1002 converts an amount of incident light an image of which is formed on the light receiving surface by the lens group 1001 into an electrical signal in units of pixels and supplies the same to the DSP circuit 1003 as a pixel signal.

The DSP circuit 1003 performs predetermined image processing on the pixel signal supplied from the solid-state imaging device 1002. Then, the DSP circuit 1003 supplies an image signal subjected to the image processing to the frame memory 1004 in units of frames to temporarily store the image signal into the frame memory 1004.

The monitor 1005 includes, for example, a panel type display device such as a liquid crystal panel or an organic electro luminescence (EL) panel. The monitor 1005 displays the image (moving image) of the subject on the basis of the pixel signal for each frame temporarily stored in the frame memory 1004.

The memory 1006 includes a DVD, a flash memory and the like. The memory 1006 reads and records the pixel signal for each frame temporarily stored in the frame memory 1004.

Note that the electronic device to which the solid-state imaging device 1 can be applied is not limited to the imaging device 1000, and the solid-state imaging device 1 can also be applied to other electronic devices.

Furthermore, the solid-state imaging device 1 according to the first embodiment is used as the solid-state imaging device 1002, but other configurations can also be employed. For example, other light detection devices to which the present technology is applied, such as the solid-state imaging device 1 according to the variation of the first embodiment, may be used.

Note that, the present technology may also have the following configuration.
(1)
A light detection device including:
a substrate including a plurality of photoelectric conversion units; and
a wiring layer arranged on a side opposite to a light receiving surface of the substrate, in which
the wiring layer includes a reflection layer formed so as to overlap at least a part of a plurality of the photoelectric conversion units in a stacking direction in which the substrate and the wiring layer are stacked, and
the reflection layer includes a plurality of recesses each including a corner cube-shaped portion in each of portions overlapping the photoelectric conversion units on a surface on a side of the photoelectric conversion units.
(2)
The light detection device according to (1) described above, in which
each of the recesses is a quadrangular prism-shaped recess in which each of corners at four corners forms a corner cube including three reflection planes and a vertex at which the three reflection planes intersect.
(3)
The light detection device according to (2) described above, in which
in the quadrangular prism-shaped recess, lengths of respective sides of an internal dimension are same.
(4)
The light detection device according to any one of (1) to (3) described above, in which
the reflection layer contains polysilicon, tungsten, or copper.
(5)
The light detection device according to any one of (1) to (4) described above, in which
the reflection layer includes a plurality of quadrangular prism-shaped protrusions on a surface on a side opposite to the substrate.
(6)
The light detection device according to any one of (1) to (5) described above, in which
an entire reflection layer is located in the wiring layer.
(7)
The light detection device according to any one of (1) to (5) described above, in which
a portion on a side of the substrate of the reflection layer is located in the substrate.
(8)
The light detection device according to any one of (1) to (7) described above, in which
the reflection layer includes reflection plates arranged corresponding to the respective photoelectric conversion units,
a part or all of the reflection plates includes the recesses on the surface on the side of the photoelectric conversion units, and
each of the reflection plates is arranged at a position not overlapping a gate electrode of a transistor formed on a surface on the side opposite to the light receiving surface of the substrate in the stacking direction.
(9)
The light detection device according to (8) described above, including:
a color filter layer arranged on a side of the light receiving surface of the substrate, in which
the color filter layer includes color filters arranged corresponding to the respective photoelectric conversion units, the color filters that transmit light of a predetermined wavelength and allow the light to be incident on the corresponding photoelectric conversion units, and
a size of each of the recesses is set for each type of the color filters corresponding to the reflection plates on which the recesses are formed.
(10)
The light detection device according to (8) or (9) described above, in which
the recesses are formed only on an outer edge of a surface on a side of the photoelectric conversion unit of the reflection plate.
(11)
The light detection device according to any one of (1) to (10) described above, further including:
a low refractive index film that covers an inner surface of each of the recesses.
(12)
The light detection device according to any one of (1) to (11) described above, in which
the substrate includes a pixel separation unit formed between the photoelectric conversion units, the pixel separation unit that extends from the light receiving surface of the substrate toward a surface on the opposite side, and includes a bottom surface in the substrate.
(13)
The light detection device according to any one of (1) to (11) described above, in which
the substrate includes a pixel separation unit formed between the photoelectric conversion units, the pixel separation unit that penetrates the substrate.
(14)
An electronic device including:
a light detection device including a substrate including a plurality of photoelectric conversion units, and a wiring layer arranged on a side opposite to a light receiving surface of the substrate, in which the wiring layer includes a reflection layer formed so as to overlap at least a part of a plurality of the photoelectric conversion units in a stacking direction in which the substrate and the wiring layer are stacked, and the reflection layer includes a plurality of recesses each including a corner cube-shaped portion in each of portions overlapping the photoelectric conversion units on a surface on a side of the photoelectric conversion units.

### REFERENCE SIGNS LIST

1 Solid-state imaging device
2 Substrate
3 Pixel region
4 Vertical drive circuit
5 Column signal processing circuit
6 Horizontal drive circuit
7 Output circuit
8 Control circuit
9 Pixel
10 Pixel drive wiring
11 Vertical signal line
12 Horizontal signal line
13 Photoelectric conversion unit
14 Transfer transistor
15 Reset transistor
16 Amplification transistor
17 Selection transistor
18 Transfer line
19 Reset line
20 Selection line
21 FD unit
22 Insulating film
23 Light shielding film
24 Planarization film
25 Light receiving layer
26 Color filter layer
27 Microlens layer
28 Light condensing layer
29 Wiring layer
30 Transfer gate electrode
31 Pixel separation unit
32 Trench
33 Incident light
34 Color filter
35 Microlens
36 Interlayer insulating film
37 Wiring
38 Reflection layer
39 Reflection plate
40 Recess
41 Corner
42 Reflection plane
43 Protrusion
44 Recess
45 Low refractive index film

1. A light detection device comprising:
a substrate including a plurality of photoelectric conversion units; and
a wiring layer arranged on a side opposite to a light receiving surface of the substrate, wherein
the wiring layer includes a reflection layer formed so as to overlap at least a part of a plurality of the photoelectric conversion units in a stacking direction in which the substrate and the wiring layer are stacked, and
the reflection layer includes a plurality of recesses each including a corner cube-shaped portion in each of portions overlapping the photoelectric conversion units on a surface on a side of the photoelectric conversion units.

2. The light detection device according to claim 1, wherein
each of the recesses is a quadrangular prism-shaped recess in which each of corners at four corners forms a corner cube including three reflection planes and a vertex at which the three reflection planes intersect.

3. The light detection device according to claim 2, wherein
in the quadrangular prism-shaped recess, lengths of respective sides of an internal dimension are same.

4. The light detection device according to claim 1, wherein
the reflection layer contains polysilicon, tungsten, or copper.

5. The light detection device according to claim 1, wherein
the reflection layer includes a plurality of quadrangular prism-shaped protrusions on a surface on a side opposite to the substrate.

6. The light detection device according to claim 1, wherein
an entire reflection layer is located in the wiring layer.

7. The light detection device according to claim 1, wherein
a portion on a side of the substrate of the reflection layer is located in the substrate.

8. The light detection device according to claim 1, wherein
the reflection layer includes reflection plates arranged corresponding to the respective photoelectric conversion units,
a part or all of the reflection plates include the recesses on the surface on the side of the photoelectric conversion units, and
each of the reflection plates is arranged at a position not overlapping a gate electrode of a transistor formed on a surface on the side opposite to the light receiving surface of the substrate in the stacking direction.

9. The light detection device according to claim 8, comprising:
a color filter layer arranged on a side of the light receiving surface of the substrate, wherein
the color filter layer includes color filters arranged corresponding to the respective photoelectric conversion units, the color filters that transmit light of a predetermined wavelength and allow the light to be incident on the corresponding photoelectric conversion units, and
a size of each of the recesses is set for each type of the color filters corresponding to the reflection plates on which the recesses are formed.

10. The light detection device according to claim 8, wherein
the recesses are formed only on an outer edge of a surface on a side of the photoelectric conversion unit of the reflection plate.

11. The light detection device according to claim 1, further comprising:
a low refractive index film that covers an inner surface of each of the recesses.

12. The light detection device according to claim 1, wherein
the substrate includes a pixel separation unit formed between the photoelectric conversion units, the pixel separation unit that extends from the light receiving surface of the substrate toward a surface on the opposite side, and includes a bottom surface in the substrate.

13. The light detection device according to claim 1, wherein
the substrate includes a pixel separation unit formed between the photoelectric conversion units, the pixel separation unit that penetrates the substrate.

14. An electronic device comprising:
a light detection device including a substrate including a plurality of photoelectric conversion units, and a wiring layer arranged on a side opposite to a light receiving surface of the substrate, wherein the wiring layer includes a reflection layer formed so as to overlap at least a part of a plurality of the photoelectric conversion units in a stacking direction in which the substrate and the wiring layer are stacked, and the reflection layer includes a plurality of recesses each including a corner cube-shaped portion in each of portions overlapping the photoelectric conversion units on a surface on a side of the photoelectric conversion units.
